(19) United States
(12) Patent Application Publication
(10) Pub. No.: US 2006/0232318 A1
(43) Pub. Date: Oct. 19, 2006

(54) Power clamp circuit and semiconductor device

(75) Inventors: Junji Iwahori, Kasugai (JP); Teruo Suzuki, Kasugai (JP); Kenji Hashimoto, Kawasaki (JP); Noriaki Saito, Kawasaki (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/216,004

(22) Filed: Sep. 1, 2005

(30) Foreign Application Priority Data
Apr. 15, 2005 (JP) 2005-118781

(51) Int. Cl. H03K 5/08

(52) U.S. Cl. 327/309

(57) ABSTRACT

A power clamp circuit for preventing unnecessary power supply leak current at a tolerable power supply noise level. A reference voltage circuit generates a reference voltage by reducing a positive voltage supplied from a first power supply terminal by a predetermined potential and supplies the reference voltage to a buffer circuit. The buffer circuit activates a transistor functioning as a clamp element based on the reference voltage to short-circuit the first and second power supply terminals.

This application is based upon and claims the benefit of priority from the prior Japanese Patent Application No. 2005-118781, filed on Apr. 15, 2005, the entire contents of which are incorporated herein by reference.

### BACKGROUND OF THE INVENTION

The present invention relates to a semiconductor device, and more particularly, to a power clamp circuit applicable to an electro-static discharge (ESD) protection circuit for protecting an internal circuit of a semiconductor device from ESD.

A typical semiconductor device (LSI) has an internal circuit configured by miniaturized semiconductor elements. The semiconductor device is therefore provided with a power clamp circuit which functions as a protection circuit for protecting the semiconductor elements from voltage surge caused by external ESD. The power clamp circuit prevents voltage exceeding a tolerable allowable level from being applied to the internal circuit.

FIG. 1 is a schematic circuit diagram showing a conventional power clamp circuit.

An LSI 52 includes a power clamp circuit 51 and an internal circuit 57. The power clamp circuit 51 includes a resistor 53, a capacitor 54, a buffer circuit 55, and an N-channel type MOS transistor 56 functioning as a clamp element. The internal circuit 57 is connected to an I/O terminal 58 used for the input and output of signals, and power supply terminals 59 and 60 for supplying power supply voltages VDD and VSS. The power supply voltage VDD is a positive power supply voltage, and the power supply voltage VSS is a negative power supply voltage.

The resistor 53 and the capacitor 54 are connected in series between the power supply terminals 59 and 60 to configure an RC circuit. The buffer circuit 55 is configured by, for example, an inverter circuit including a P-channel type MOS transistor 61 and an N-channel type MOS transistor 62. The buffer circuit 55 is supplied with the potential at a node between the resistor 53 and the capacitor 54. This potential functions as an input signal. The transistor 56 functioning as a clamp element has a source connected to the power supply terminal 60, a drain connected to the power supply terminal 59, and a gate provided with an output signal from the buffer circuit 55.

In the power clamp circuit 51, during a normal state, a signal having the same potential as the power supply voltage VDD is provided to the buffer circuit 55 from a node between the resistor 53 and the capacitor 54. An L (low) level signal is then provided to the transistor 56 from the signal buffer circuit 55 so as to inactivate the transistor 56 (clamp element). Accordingly, the power supply voltage VDD is provided to the internal circuit 57 and the internal circuit 57 performs a predetermined operation.

When a positive ESD surge relative to the power supply voltage VDD is applied to the power supply terminal 59, the ESD surge causes electric current to flow to the RC circuit, which is configured by the resistor 53 and the capacitor 54. This charges the capacitor 54 in accordance with the RC time constant of the resistor 53 and the capacitor 54. During the RC time constant when the capacitor 54 is being charged, the transistor 61 of the buffer circuit 55 is activated so that an H (high) level signal is provided from the buffer circuit 55 to the transistor 56 (clamp element) to activate the transistor 56. Accordingly, the electric current resulting from the ESD surge flows to the power supply voltage VSS via the activated transistor 56. This flow of electric current protects the internal circuit 57 from the electric current resulting from the ESD surge. Such a conventional power clamp circuit 51 is described, for example, by Richard Merrill and Enayet Issaq, in “ESD Design Methodology”, EOS/ESD Symposium, pp. 93-233.

### SUMMARY OF THE INVENTION

However, an H level signal is output from the buffer circuit 55 to the transistor 56 to activate the transistor 56 on, not only when a high voltage surge such as ESD is applied to the power supply terminal 59, but also when power supply noise having a displacement potential that is greater than or equal to the voltage that activates the transistor 61 of the buffer circuit 55 (i.e., the threshold voltage) is applied to the power supply terminal 59. Therefore, even if the power supply noise is at a tolerable level that will not affect the internal circuit 57, the transistor 56 (clamp element) may be activated by such power supply noise. In such a case, undesired power supply leak current flows through the activated transistor 56 during the RC time constant when the capacitor 54 is being charged. Such a power supply leak current increases current consumption. Especially when the LSI 52 configures a battery device, such an undesirable power supply leak current will accelerate the consumption of battery current.

The present invention provides a power clamp circuit which is capable of preventing the generation of unnecessary power supply leak current at tolerable power supply noise levels. The present invention also provides a semiconductor device having such a power clamp circuit.

One aspect of the present invention is a power clamp circuit provided with an RC circuit including a resistor and a capacitor connected in series between a first power supply terminal, for supplying a first power supply voltage functioning as a positive voltage, and a second power supply terminal, for supplying a second power supply voltage functioning as a negative voltage. A clamp element is connected between the first and second power supply terminals so as to become conductive or non-conductive in response to an input signal to selectively cause short-circuiting between the first and second power supply terminals. A buffer circuit generates the input signal provided to the clamp element based on a potential at a node between the resistor and the capacitor and a reference voltage. A reference voltage circuit, connected to the buffer circuit, generates the reference voltage by reducing the first power supply voltage by a predetermined potential or by raising the second power supply voltage by a predetermined potential and providing the reference voltage to the buffer circuit.

Another aspect of the present invention is a semiconductor device including an internal circuit and a power clamp circuit connected to the internal circuit. The power clamp circuit includes an RC circuit including a resistor and a capacitor connected in series between a first power supply terminal, for supplying a first power supply voltage functioning as a positive voltage, and a second power supply terminal, for supplying a second power supply voltage functioning as a negative voltage. A clamp element is connected between the first and second power supply terminals so as to become conductive or non-conductive in response to an input signal to selectively cause short-circuiting between the first and second power supply terminals. A buffer circuit generates the input signal provided to the clamp element based on a potential at a node between the resistor and the capacitor and a reference voltage. A reference voltage circuit, connected to the buffer circuit, generates the reference voltage by reducing the first power supply voltage by a predetermined potential or by raising the second power supply voltage by a predetermined potential and providing the reference voltage to the buffer circuit.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a schematic circuit diagram showing a power clamp circuit in the prior art;

FIG. 2 is a schematic circuit diagram showing a power clamp circuit according to a first embodiment of the present invention;

FIG. 3 is a schematic circuit diagram showing a reference voltage circuit of the power clamp circuit shown in FIG. 2;

FIG. 4 is a schematic circuit diagram showing a modification of the reference voltage circuit of FIG. 3;

FIG. 5 is a schematic circuit diagram showing a further modification of the reference voltage circuit of FIG. 3;

FIG. 6 is a schematic circuit diagram showing a power clamp circuit according to a second embodiment of the present invention;

FIG. 7 is a schematic circuit diagram showing a modification of the power clamp circuit of FIG. 6;

FIG. 8 is a schematic circuit diagram showing a power clamp circuit according to a third embodiment of the present invention; and

FIG. 9 is a schematic circuit diagram showing a modification of the power clamp circuit of FIG. 8.

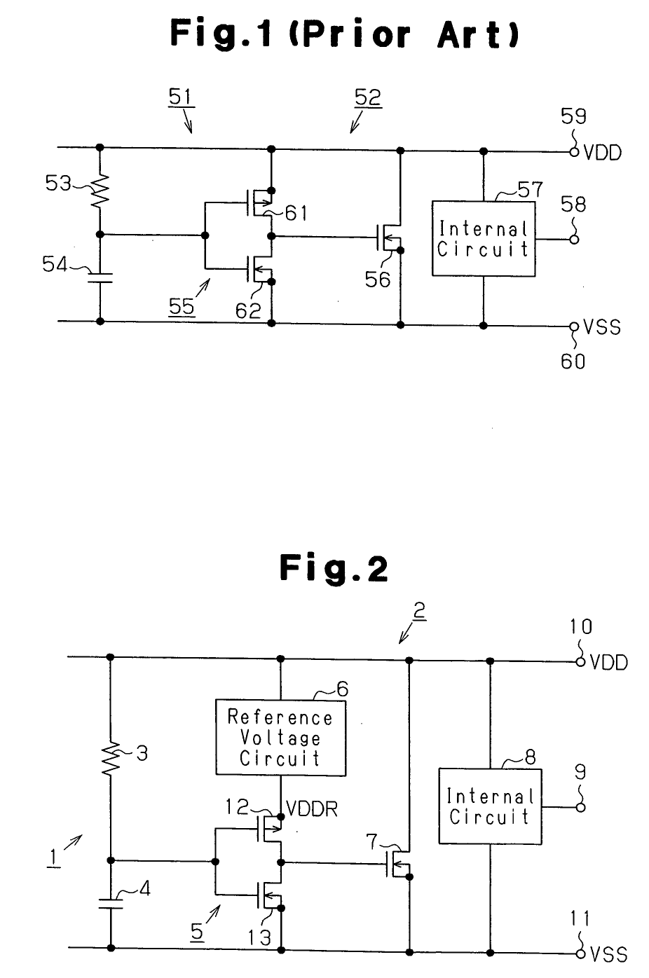

### DETAILED DESCRIPTION OF THE PREFERRED EMBODIMENTS

In the drawings, like numerals are used for like elements throughout.

A power clamp circuit 1 according to a first embodiment of the present invention will now be described with reference to FIGS. 2 to 5.

FIG. 2 is a schematic circuit diagram showing the power clamp circuit 1 according to a first embodiment of the present invention.

A semiconductor device 2, which is preferably an LSI, includes the power clamp circuit 1 and an internal circuit 8. The power clamp circuit 1 includes a resistor 3, a capacitor 4, a buffer circuit 5, a reference voltage circuit 6, and an N-channel type MOS transistor 7 functioning as a clamp element. The internal circuit 8 is connected to an I/O terminal 9 for input and output of signals, a first power supply terminal 10 for supplying a first power supply voltage VDD, and a second power supply terminal 11 for supplying a second power supply voltage VSS. The first power supply voltage VDD is a positive voltage, and the second power supply voltage VSS is a negative voltage.

The resistor 3 and the capacitor 4 are connected in series between the power supply terminals 10 and 11 to configure an RC circuit. The buffer circuit 5 is preferably an inverter circuit including a P-channel type MOS transistor (hereafter, referred to as “first transistor”) 12 and an N-channel type MOS transistor (hereafter, referred to as “second transistor”) 13. The source of the first transistor 12 is connected to the first power supply terminal 10 via the reference voltage circuit 6. The source of the second transistor 13 is connected to the second power supply terminal 11. The buffer circuit 5 is provided with a potential at a node between the resistor 3 and the capacitor 4. This potential functions as an input signal.

The reference voltage circuit 6 reduces the first power supply voltage VDD by a predetermined potential to generate a reference voltage VDDR, and supplies the generated reference voltage VDDR to the source of the first transistor 12. A voltage reduction amount Vd (VDD-VDDR) of the first power supply voltage VDD in the reference voltage circuit 6 is set such that the first transistor 12, or the transistor 7 (clamp element), will not be activated by a displacement potential within a tolerable range of power supply noise that may occur in the first power supply voltage VDD. Specifically, the voltage reduction amount Vd is set to a value which satisfies the relationship of Vd>Np−Vth. In this expression, Np represents the tolerable power supply noise level, and Vth represents the threshold voltage of the first transistor 12.

The transistor 7 has a source connected to the second power supply terminal 11, a drain connected to the first power supply terminal 10, and a gate for receiving an output signal from the buffer circuit 5.

In the power clamp circuit 1, in a normal state, a signal having the same potential as the first power supply voltage VDD is provided to the buffer circuit 5 from a node between the resistor 3 and the capacitor 4. Consequently, an L level signal is provided from the buffer circuit 5 to the transistor 7 (clamp element) to inactivate the transistor 7. Thus, the first power supply voltage VDD is supplied to the internal circuit 8, and the internal circuit 8 performs a predetermined operation.

If a positive ESD surge exceeding the tolerable noise level for the first power supply voltage VDD is applied to the first power supply terminal 10, electric current resulting from the ESD surge will flow to the RC circuit configured by the resistor 3 and the capacitor 4. This charges the capacitor 4 in accordance with the RC time constant of the resistor 3 and the capacitor 4. During the RC time constant when the capacitor 4 is being charged, the first transistor 12 of the buffer circuit 5 is activated, an H level signal is provided from the buffer circuit 5 to the transistor 7, and the transistor 7 is activated. Therefore, the electric current resulting from the ESD surge will flow to the second power supply terminal 11 through the activated transistor 7. This protects the internal circuit 8 from the electric current resulting from the ESD surge.

If a power supply noise within an tolerable range for the first power supply voltage VDD, that is, a power supply noise having a displacement amount not exceeding the sum of the voltage reduction amount Vd in the reference voltage circuit 6 and the threshold voltage Vth of the first transistor 12, is applied to the first power supply terminal 10, the input gate level of the buffer circuit 5 will not reach a level exceeding the threshold voltage Vth of the first transistor 12. Therefore, the first transistor 12 is not activated. Consequently, an L level signal is provided from the buffer circuit 5 to the transistor 7 to keep the transistor 7 inactivated. In other words, the transistor 7 is not activated. This prevents the occurrence of unnecessary power supply leak current at tolerable power supply noise levels.

The circuit configuration of the reference voltage circuit 6 will now be described.

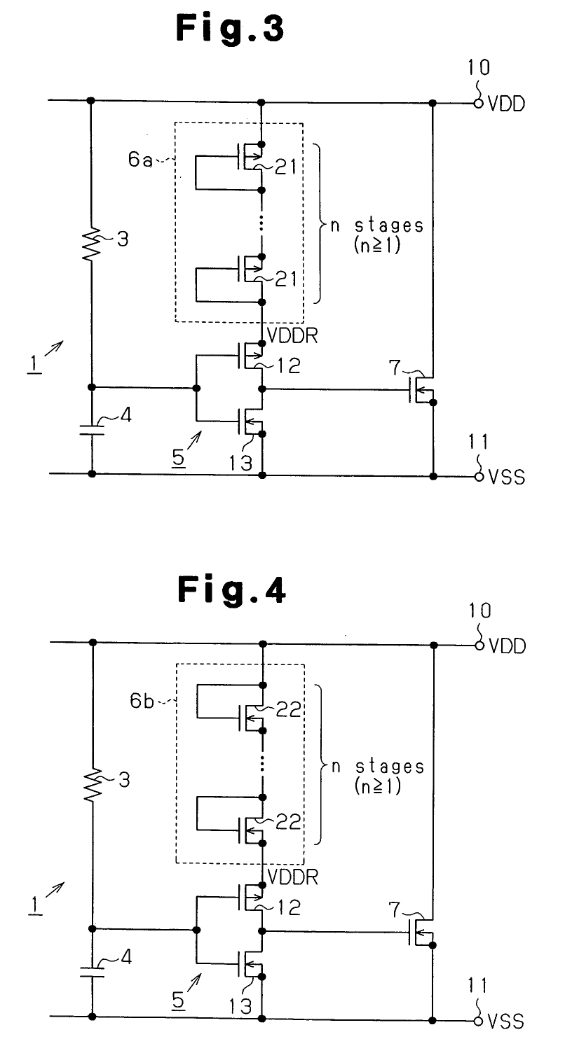

FIG. 3 shows a reference voltage circuit 6a as one example of the reference voltage circuit 6. The reference voltage circuit 6a includes n (n≧1) stages of P-channel type MOS transistors 21 connected in series. Each of the transistors 21 configures a diode or is diode-connected (hereafter, the transistor 21 is referred to as the “PMOS diode 21”). A single PMOS diode 21 may be used instead of a plurality of the PMOS diodes 21. The voltage reduction amount Vd of the reference voltage circuit 6a is set based on the threshold voltage of the n stages of PMOS diodes 21 so as to satisfy the above-mentioned relationship of Vd>Np−Vth. The condition for activating the transistor 7 (clamp element) may be set in any manner.

FIG. 4 shows a reference voltage circuit 6b as another example of the reference voltage circuit 6. The reference voltage circuit 6bincludes n (n≧1) stages of N-channel type MOS transistors 22 connected in series. Each of the transistors 22 configures a diode (hereafter, the transistor 22 is referred as the “NMOS diode 22”). A single NMOS diode 22 may be used instead of a plurality of NMOS diodes 22. The voltage reduction amount Vd of the reference voltage circuit 6bis set based on the threshold voltage of the n stages of NMOS diodes 22 so as to satisfy the above-mentioned relationship of Vd>Np−Vth. The condition for activating the transistor 7 (clamp element) may be set in any manner.

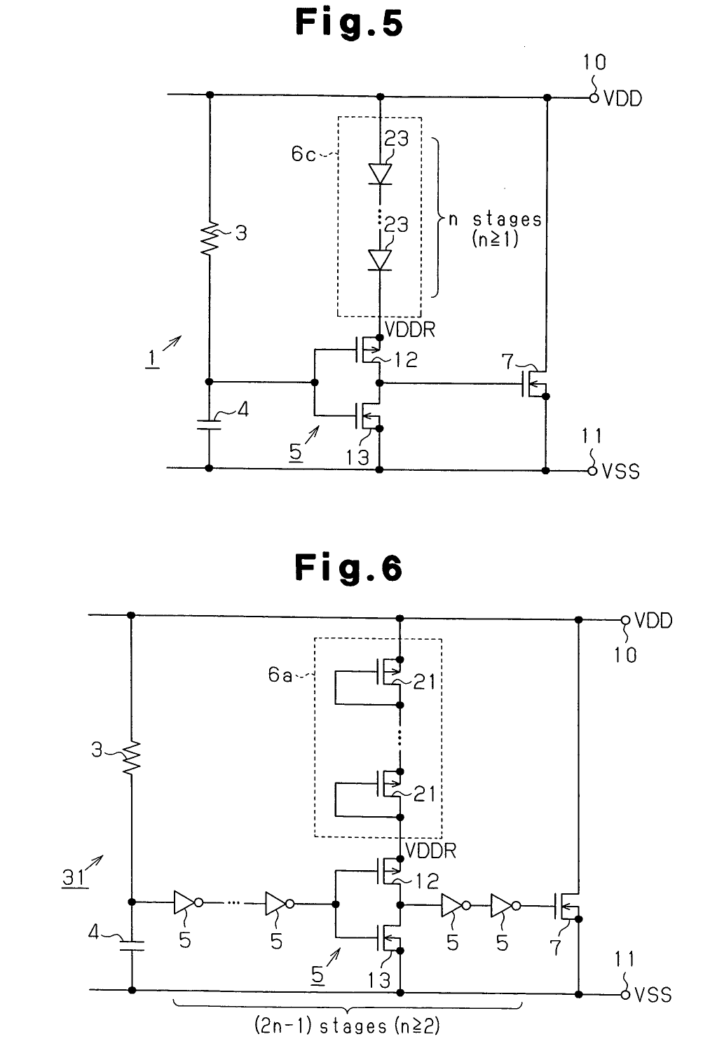

FIG. 5 shows a reference voltage circuit 6c as a further example of the reference voltage circuit 6. The reference voltage circuit 6c includes n (n≧1) stages of diodes 23 connected in series. Each of the diodes has an anode connected to the first power supply terminal 10 directly or via one or more diodes, and a cathode connected to the second power supply terminal 11 directly or via one or more diodes. A single diode 23 may be used instead of a plurality of the diodes 23. The voltage reduction amount Vd of the reference voltage circuit 6c is set based on the threshold voltage of the n stages of diodes 23 so as to satisfy the above-mentioned relationship of Vd>Np−Vth. The condition for activating the transistor 7 (clamp element) may be set in any manner.

The power clamp circuit 1 of the first embodiment has the advantages described below.

The power clamp circuit 1 includes the reference voltage circuit 6 for reducing the first power supply voltage VDD by a predetermined potential (voltage reduction amount Vd) to generate a reference voltage VDDR, and supplying the reference voltage VDDR to the buffer circuit 5. The reference voltage circuit 6 provides the reference voltage VDDR such that the transistor 7 (clamp element) is activated when power supply noise exceeding the sum of the voltage reduction amount Vd of the reference voltage circuit 6 and the threshold voltage Vth of the first transistor 12 is generated in the first power supply voltage VDD. This prevents unnecessary power supply leak current at tolerable power supply noise levels.

A power clamp circuit 31 according to a second embodiment of the present invention will now be described with reference to FIG. 6 focusing on the differences from the power clamp circuit 1 of the first embodiment.

The power clamp circuit 31 according to the second embodiment includes (2n−1) stages of (i.e., an odd number of stages satisfying n≧2) buffer circuits 5 and a reference voltage circuit 6a (FIG. 3). The buffer circuits 5 are connected in series between the transistor 7 and a node between the resistor 3 and the capacitor 4. The reference voltage circuit 6a is connected to at least one of the (2n−1) stages of buffer circuits 5 (except for the final buffer circuit). The reference voltage circuit 6a may be replaced by the reference voltage circuit 6b (FIG. 4) or the reference voltage circuit 6c (FIG. 5).

Each of the buffer circuits 5 is preferably configured by an inverter circuit. In the second embodiment, among the (2n−1) buffer circuits 5, the reference voltage circuit 6a is connected between the first power supply terminal 10 and the source of the first transistor 12 of the (2n−3)th stage of the buffer circuits 5. Thus, the first power supply voltage VDD is directly supplied from the first power supply terminal 10 to the sources of the first transistor 12 (not shown) of each buffer circuit 5 excluding the (2n−3)th stage buffer circuit 5. The voltage reduction amount Vd of the reference voltage circuit 6a is set so as to satisfy the relationship of Vd>Np−Vth.

When a tolerable level of power supply noise is applied to the first power supply terminal 10 in the power clamp circuit 31, an L level signal is provided to the transistor 7 from the final, (2n−1)th stage buffer circuit 5 to keep the transistor 7 off. In this case, an output signal from the (2n−3)th stage buffer circuit 5 prevents the final buffer circuit 5 from outputting an H level signal, which would activate the transistor 7. In this manner, unnecessary power supply leak current at tolerable power supply noise levels is prevented.

When a voltage surge exceeding the tolerable noise level such as ESD is applied to the first power supply terminal 10, an H level signal is provided from the final buffer circuit 5 to the transistor 7 to activate the transistor 7. In this case, the first power supply voltage VDD is directly provided to the source of the first transistor 12 of each buffer circuit 5 except for the (2n−3)th stage buffer circuit 5. Therefore, the switching responsiveness of the transistor 7 remains satisfactory even when a high voltage surge such as ESD is applied. As a result, the protective function against ESD is maintained in a satisfactory manner.

The power clamp circuit 31 of the second embodiment has the advantages described below.

The power clamp circuit 31 includes a plurality of (an odd number of) the buffer circuits 5 and the reference voltage circuit 6, which is connected to at least one of the buffer circuits 5 (except for the final buffer circuit). This configuration prevents unnecessary power supply leak current at a tolerable noise level while maintaining the protective function against ESD in an optimal manner.

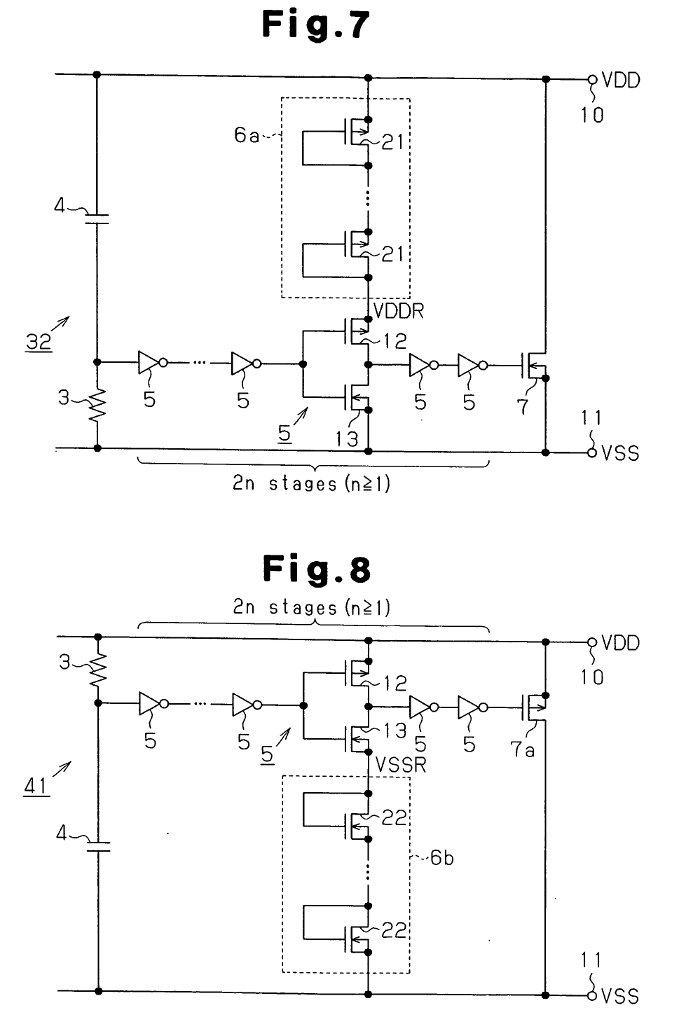

FIG. 7 is a schematic circuit diagram showing a power clamp circuit 32, which is a modification of the power clamp circuit 31 of the second embodiment.

The power clamp circuit 32 includes 2n stages of (i.e., an even number of stages satisfying n≧1) buffer circuits 5. In this configuration, the connection positions of the resistor 3 and the capacitor 4 between the first and second power supply terminals 10 and 11 are changed. Specifically, one end of the capacitor 4 is connected to the first power supply terminal 10, and one end of the resistor 3 is connected to the second power supply terminal 11.

At least one of the 2n stages of buffer circuits 5 (except the final buffer circuit) is connected to the reference voltage circuit 6a. In this modification, the reference voltage circuit 6a is connected to the (2n−2)th stage buffer circuit 5. The reference voltage circuit 6a may be replaced by the reference voltage circuit 6b (FIG. 4) or the reference voltage circuit 6c (FIG. 5) The power clamp circuit 32 has the same advantages as the power clamp circuit 31 of the second embodiment.

A power clamp circuit 41 according to a third embodiment of the present invention will now be described with reference to FIG. 8 focusing on the differences from the above embodiments.

The power clamp circuit 41 counters power supply noise, which may be produced at the side of the second power supply voltage VSS, in a manner similar to the above embodiments. Specifically, the N-channel type MOS transistor 7, which functions as a clamp element, is replaced by a P-channel type MOS transistor 7a, and the reference voltage circuit 6b (see FIG. 4) is connected between the second power supply terminal 11 and the source of the second transistor 13 of the buffer circuit 5. The reference voltage circuit 6b may be replaced by the reference voltage circuit 6a (FIG. 3) or the reference voltage circuit 6c (FIG. 5).

The power clamp circuit 41 includes 2n stages of buffer circuits 5 (i.e., an even number of stages satisfying n>1), with each buffer circuit being configured by an inverter circuit. At least one of the 2n buffer circuits 5 (except the final buffer circuit) is connected to the reference voltage circuit 6b.

In the third embodiment, the reference voltage circuit 6b is connected to the (2n−2)th stage buffer circuit 5. The reference voltage circuit 6b raises the second power supply voltage VSS by a predetermined potential to generate a reference voltage VSSR, and provides the reference voltage VSSR to the source of the second transistor 13. A voltage increase amount Vu of the second power supply voltage VSS in the reference voltage circuit 6b is set to satisfy the relationship of Vd>Np−Vth1 with respect to a threshold voltage Vth1 of the second transistor 13. The second power supply voltage VSS is directly provided from the second power supply terminal 11 to the source of the second transistors 13 (not shown) of each buffer circuit 5 except for the (2n−2)th stage buffer circuit. In the third embodiment, unnecessary power supply leak current at tolerable noise levels is prevented while optimally maintaining the protective function against ESD surge or power supply noise that may occur in the second power supply voltage VSS.

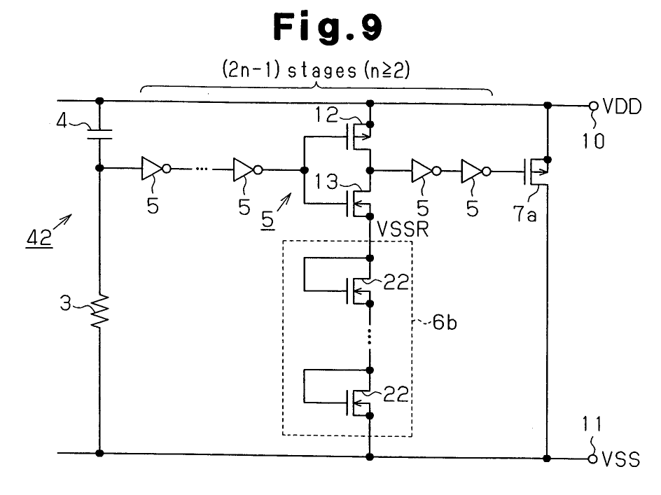

FIG. 9 is a schematic circuit diagram of a power clamp circuit 42, which is a modification of the power clamp circuit 41 of the third embodiment.

The power clamp circuit 42 includes (2n−1) stages of (i.e., an odd number of stages satisfying n≧2) buffer circuits 5. In this configuration, the connection positions of the resistor 3 and the capacitor 4 between the first and second power supply terminals 10 and 11 are changed. Specifically, one end of the capacitor 4 is connected to the first power supply terminal 10, and one end of the resistor 3 is connected to the second power supply terminal 11. The other parts are the same as the power clamp circuit 41 shown in FIG. 8.

At least one of the (2n−1) stages of buffer circuits 5 (except the final buffer circuit) is connected to the reference voltage circuit 6b (see FIG. 4). In this modification, the (2n−3)th stage buffer circuit 5 is connected to the reference voltage circuit 6b. The reference voltage circuit 6b may be replaced by the reference voltage circuit 6a (FIG. 3) or the reference voltage circuit 6c (FIG. 5). The power clamp circuit 42 also has the same advantages as the power clamp circuit 41 of the third embodiment.

It should be apparent to those skilled in the art that the present invention may be embodied in many other specific forms without departing from the spirit or scope of the invention. Particularly, it should be understood that the present invention may be embodied in the following forms.

In the second and third embodiments (and their modifications), the reference voltage circuit 6 (6a, 6b or 6c) may be connected to any of the plurality of buffer circuits 5 excluding at least the final buffer circuit 5.

The configuration of the reference voltage circuit 6 is not limited to those shown in FIGS. 3 to 5, and the reference voltage circuit 6 may have any configuration.

The present examples and embodiments are to be considered as illustrative and not restrictive, and the invention is not to be limited to the details given herein, but may be modified within the scope and equivalence of the appended claims.

What is claimed is:

1. A power clamp circuit comprising:
an RC circuit including a resistor and a capacitor connected in series between a first power supply terminal, for supplying a first power supply voltage functioning as a positive voltage, and a second power supply terminal, for supplying a second power supply voltage functioning as a negative voltage;
a clamp element connected between the first and second power supply terminals so as to become conductive or non-conductive in response to an input signal to selectively cause short-circuiting between the first and second power supply terminals;
a buffer circuit for generating the input signal provided to the clamp element based on a potential at a node between the resistor and the capacitor and a reference voltage; and
a reference voltage circuit, connected to the buffer circuit, for generating the reference voltage by reducing the first power supply voltage by a predetermined potential or by raising the second power supply voltage by a predetermined potential and providing the reference voltage to the buffer circuit.

2. The power clamp circuit according to claim 1, wherein the buffer circuit includes an inverter circuit having a first transistor and a second transistor, with the reference voltage circuit being connected between the first power supply terminal and a source of the first transistor or connected between the second power supply terminal and a source of the second transistor.

3. The power clamp circuit according to claim 1, wherein the buffer circuit is one of an odd number or an even number of buffer circuits, with the reference voltage circuit being connected to at least one of the odd number or even number of buffer circuits.

4. The power clamp circuit according to claim 3, wherein the reference voltage circuit is connected to at least one of the odd number or even number of buffer circuits except a final one of the buffer circuits that is connected to the clamp element.

5. The power clamp circuit according to claim 1, wherein when the first power supply voltage or the second power supply voltage contains power supply noise of a tolerable level, the reference voltage circuit generates the reference voltage such that the buffer circuit generates the input signal to cause the clamp element to be non-conductive.

6. The power clamp circuit according to claim 5, wherein the buffer circuit includes an inverter circuit having a first transistor, connected to the first power supply terminal via the reference voltage circuit, and a second transistor, connected between the first transistor and the second power supply terminal, the predetermined potential by which the first power supply voltage is reduced is set so as to be greater than a value obtained by subtracting a threshold voltage of the first transistor from the tolerable level.

7. The power clamp circuit according to claim 5, wherein the buffer circuit includes an inverter circuit having a first transistor, connected to the first power supply terminal, and a second transistor having a first terminal, connected to the first transistor, and a second terminal, connected to the second power supply terminal via the reference voltage circuit, the predetermined potential by which the second power supply voltage is raised is set so as to be greater than a value obtained by subtracting a threshold voltage of the second transistor from the tolerable level.

8. The power clamp circuit according to claim 1, wherein the reference voltage circuit includes one or more diodes.

9. The power clamp circuit according to claim 8, wherein the one or more diodes include a transistor configured as a diode.

10. A semiconductor device comprising:
an internal circuit; and
a power clamp circuit connected to the internal circuit, the power clamp circuit including:
an RC circuit including a resistor and a capacitor connected in series between a first power supply terminal, for supplying a first power supply voltage functioning as a positive voltage, and a second power supply terminal, for supplying a second power supply voltage functioning as a negative voltage;
a clamp element connected between the first and second power supply terminals so as to become conductive or non-conductive in response to an input signal to selectively cause short-circuiting between the first and second power supply terminals;
a buffer circuit for generating the input signal provided to the clamp element based on a potential at a node between the resistor and the capacitor and a reference voltage; and
a reference voltage circuit, connected to the buffer circuit, for generating the reference voltage by reducing the first power supply voltage by a predetermined potential or by raising the second power supply voltage by a predetermined potential and providing the reference voltage to the buffer circuit.

11. The semiconductor device according to claim 10, wherein the buffer circuit includes an inverter circuit having a first transistor and a second transistor, the reference voltage circuit being connected between the first power supply terminal and a source of the first transistor or connected between the second power supply terminal and a source of the second transistor.

12. The semiconductor device according to claim 10, wherein the buffer circuit is one of an odd number or an even number of buffer circuits, the reference voltage circuit being connected to at least one of the odd number or even number of buffer circuits.

13. The semiconductor device according to claim 12, wherein the reference voltage circuit is connected to at least one of the odd number or even number of buffer circuits except a final one of the buffer circuits that is connected to the clamp element.

14. The semiconductor device according to claim 10, wherein when the first power supply voltage or the second power supply voltage contains power supply noise of a tolerable level, the reference voltage circuit generates the reference voltage such that the buffer circuit generates the input signal to cause the clamp element to be non-conductive.

15. The semiconductor device according to claim 14, wherein the buffer circuit includes an inverter circuit having a first transistor, connected to the first power supply terminal via the reference voltage circuit, and a second transistor, connected between the first transistor and the second power supply terminal, the predetermined potential by which the first power supply voltage is reduced is set so as to be greater than a value obtained by subtracting a threshold voltage of the first transistor from the tolerable level.

16. The semiconductor device according to claim 14, wherein the buffer circuit includes an inverter circuit having a first transistor, connected to the first power supply terminal, and a second transistor having a first terminal, connected to the first transistor, and a second terminal, connected to the second power supply terminal via the reference voltage circuit, the predetermined potential by which the second power supply voltage is raised is set so as to be greater than a value obtained by subtracting a threshold voltage of the second transistor from the tolerable level.

17. The semiconductor device according to claim 10, wherein the reference voltage circuit includes one or more diodes.

18. The semiconductor device according to claim 17, wherein the one or more diodes include a transistor configured as a diode.
